(19) United States
(12) Patent Application Publication
(10) Pub. No.: US 2025/0381639 A1
(43) Pub. Date: Dec. 18, 2025

(54) METHOD OF INSPECTING SPECTRUM OF REFLECTED LIGHT FROM WORKPIECE, AND POLISHING APPARATUS

(71) Applicant: EBARA CORPORATION, Tokyo (JP)

(72) Inventors: Ching Wei HUANG, Tokyo (JP); Keita YAGI, Tokyo (JP); Yuki WATANABE, Tokyo (JP)

(21) Appl. No.: 19/233,866

(22) Filed: Jun. 10, 2025

(30) Foreign Application Priority Data
Jun. 14, 2024 (JP) 2024-096454

(51) Int. Cl. B24B 37/013; G01B 11/06

(52) U.S. Cl. CPC B24B 37/013; G01B 11/0625; G01B 11/0683

(57) ABSTRACT

A technique is closed for inspecting a spectrum of light reflected from a workpiece, such as a wafer, while the workpiece is being polished. The method includes: irradiating a plurality of film-thickness measurement points on the workpiece with light from an optical sensor head in each time segment during polishing of the workpiece; generating a plurality of measurement spectra of reflected light from the plurality of film-thickness measurement points; calculating a plurality of features of the plurality of measurement spectra; performing data mapping by plotting, on a coordinate system, a plurality of measurement data points specified by a plurality of times at which the plurality of measurement spectra were generated and the plurality of features; determining a correction index value representing the number of measurement data points existing within a threshold range defined on the coordinate system for each time segment; and determining whether the correction index value is within a correction management range.

### CROSS REFERENCE TO RELATED APPLICATION

This document claims priority to Japanese Patent Application No. 2024-096454 filed Jun. 14, 2024, the entire contents of which are hereby incorporated by reference.

### BACKGROUND

Manufacturing processes for semiconductor devices include various steps, such as polishing an insulating film (e.g., SiO₂) and polishing a metal film (copper or tungsten). A wafer is polished using a polishing apparatus. The polishing apparatus typically includes a polishing table that supports a polishing pad, a polishing head that presses the wafer against the polishing pad, and a slurry supply nozzle that supplies slurry onto the polishing pad. While the polishing table is rotated, the slurry is supplied onto the polishing pad on the polishing table, and the polishing head presses the wafer against the polishing pad. The wafer is brought into sliding contact with the polishing pad in the presence of the slurry. The surface of the wafer is planarized by a combination of a chemical action of the slurry and a mechanical action of the polishing pad and abrasive grains contained in the slurry.

Polishing of the wafer is terminated when a thickness of a film (such as an insulating film, a metal film, or a silicon layer) constituting the surface of the wafer reaches a predetermined target value. The polishing apparatus typically includes an optical film-thickness measuring device for measuring a thickness of a non-metallic film, such as an insulating film or a silicon layer. This optical film-thickness measuring device is configured to direct light of a light source to the surface of the wafer, measure intensity of the light reflected from the wafer with a spectrometer, and analyze a spectrum of the reflected light to measure the film thickness of the wafer.

Due to a malfunction or aging of the light source or optical system, the intensity of the reflected light from the wafer may change, resulting in an abnormal spectrum obtained. In another example, when a wafer of a type different from a target wafer to be polished is transported to the polishing apparatus, a spectrum of reflected light from that wafer is obtained as an abnormal spectrum. Such an abnormal spectrum causes a failure in film thickness measurement. Furthermore, if a polishing operation for a wafer is controlled based on a film-thickness measured value obtained from the abnormal spectrum, a desired polishing result will not be obtained.

### SUMMARY

Thus, there is provided a technique for inspecting a spectrum of light reflected from a workpiece, such as a wafer, while the workpiece is being polished.

Embodiments, which will be described below, relate to a technique for measuring a film thickness of a workpiece, such as a wafer, substrate, or panel, based on a spectrum of reflected light from the workpiece, and more particularly to a technique for detecting an anomaly in the spectrum of light reflected from the workpiece.

In an embodiment, there is provided a method of inspecting a spectrum of reflected light from a workpiece, comprising: polishing the workpiece by pressing the workpiece against a polishing pad on a polishing table while rotating the polishing table; irradiating a plurality of film-thickness measurement points on the workpiece with light from an optical sensor head in each time segment during polishing of the workpiece; generating a plurality of measurement spectra of reflected light from the plurality of film-thickness measurement points; calculating a plurality of features of the plurality of measurement spectra; performing data mapping by plotting, on a coordinate system, a plurality of measurement data points specified by a plurality of times at which the plurality of measurement spectra were generated and the plurality of features of the plurality of measurement spectra; determining a correction index value representing the number of measurement data points existing within a threshold range defined on the coordinate system for each time segment; and determining whether the correction index value is within a correction management range.

In an embodiment, the method further comprises correcting the plurality of features by moving the plurality of measurement data points on the coordinate system until the plurality of measurement data points fall within the threshold range when the correction index value is within the correction management range.

In an embodiment, the method further comprises generating an alarm signal when the correction index value is smaller than a lower limit of the correction management range.

In an embodiment, the method further comprises: polishing a reference workpiece by pressing a reference workpiece against the polishing pad while rotating the polishing table; irradiating a plurality of film-thickness measurement points on the reference workpiece with the light from the optical sensor head in each time segment during polishing of the reference workpiece; generating a plurality of reference spectra of reflected light from the plurality of film-thickness measurement points; calculating a plurality of features of the plurality of reference spectra; performing data mapping by plotting, on the coordinate system, a plurality of reference data points specified by a plurality of times at which the plurality of reference spectra were generated and the plurality of features of the plurality of reference spectra; and creating a threshold range for each time segment during polishing of the reference workpiece based on the plurality of reference data points on the coordinate system.

In an embodiment, the threshold range is a range within a predetermined Mahalanobis distance from a datum point of the plurality of reference data points.

In an embodiment, the method further comprises: updating the plurality of reference data points by adding the plurality of measurement data points to the plurality of reference data points when the correction index value is larger than an upper limit of the correction management range; and updating the threshold range based on the plurality of updated reference data points.

In an embodiment, the method further comprises selecting either a first set of threshold ranges or a second set of threshold ranges based on a change in the plurality of measurement data points over time as the workpiece is polished, wherein the threshold range is one of a plurality of threshold ranges in the selected one of the first set and the second set, the first set of threshold ranges is predetermined from a plurality of reference data points obtained during polishing of a first reference workpiece, and the second set of threshold ranges is predetermined from a plurality of reference data points obtained during polishing of a second reference workpiece having a different surface structure than that of the first reference workpiece.

In an embodiment, the reference workpiece comprises a first reference workpiece and a second reference workpiece, and the method further comprises creating a plurality of threshold ranges corresponding to different time segments by combining a first threshold range created from a plurality of reference data points obtained during polishing of the first reference workpiece and a second threshold range created from a plurality of reference data points obtained during polishing of the second reference workpiece.

In an embodiment, the optical sensor head comprises a first optical sensor head and a second optical sensor head disposed at different positions within the polishing table, and the method further comprises creating a plurality of threshold ranges corresponding to different time segments by combining a first threshold range created from a plurality of reference data points obtained by light irradiation from the first optical sensor head during polishing of the reference workpiece and a second threshold range created from a plurality of reference data points obtained by light irradiation from the second optical sensor head during polishing of the reference workpiece.

In an embodiment, each of the plurality of features includes at least a k-th principal component (k is a natural number) obtained by performing principal component analysis on a data set including a plurality of intensities of the reflected light at a plurality of wavelengths of each measurement spectrum.

In an embodiment, the method further comprises creating a plurality of new threshold ranges corresponding to consecutive time segments from a plurality of measurement data points acquired in the consecutive time segments when the correction index value is smaller than a lower limit of the correction management range in the consecutive time segments during polishing of the workpiece.

In an embodiment, there is provided a polishing apparatus for a workpiece, comprising: a polishing table; a table motor configured to rotate the polishing table; a polishing head configured to press the workpiece against a polishing pad on the polishing table to polish the workpiece; an optical sensor head configured to emit light to a plurality of film-thickness measurement points on the workpiece in each time segment during polishing of the workpiece; and a processing system configured to generate a plurality of measurement spectra of reflected light from the plurality of film-thickness measurement points, wherein the processing system is configured to: calculate a plurality of features of the plurality of measurement spectra; perform data mapping by plotting, on a coordinate system, a plurality of measurement data points specified by a plurality of times at which the plurality of measurement spectra were generated and the plurality of features of the plurality of measurement spectra; determine a correction index value representing the number of measurement data points existing within a threshold range defined on the coordinate system for each time segment; and determine whether the correction index value is within a correction management range.

In an embodiment, the processing system is configured to correct the plurality of features by moving the plurality of measurement data points on the coordinate system until the plurality of measurement data points fall within the threshold range when the correction index value is within the correction management range.

In an embodiment, the processing system is configured to generate an alarm signal when the correction index value is smaller than a lower limit of the correction management range.

In an embodiment, the processing system is configured to select either a first set of threshold ranges or a second set of threshold ranges based on a change in the plurality of measurement data points over time as the workpiece is polished, wherein the threshold range is one of a plurality of threshold ranges in the selected one of the first set and the second set, the first set of threshold ranges is predetermined from a plurality of reference data points obtained during polishing of a first reference workpiece, and the second set of threshold ranges is predetermined from a plurality of reference data points obtained during polishing of a second reference workpiece having a different surface structure than that of the first reference workpiece.

In an embodiment, the processing system is configured to: perform a principal component analysis on a data set including a plurality of intensities of the reflected light at a plurality of wavelengths of each measurement spectrum; and determine a feature including at least a k-th principal component (k is a natural number) obtained from the principal component analysis.

In an embodiment, the processing system is configured to create a plurality of new threshold ranges corresponding to consecutive time segments from a plurality of measurement data points acquired in the consecutive time segments when the correction index value is smaller than a lower limit of the correction management range in the consecutive time segments during polishing of the workpiece.

In an embodiment, the processing system is configured to determine the threshold range, the threshold range being within a predetermined Mahalanobis distance from a datum point of a plurality of reference data points obtained from polishing a reference workpiece.

In an embodiment, the processing system is configured to: update the plurality of reference data points by adding the plurality of measurement data points to the plurality of reference data points when the correction index value is larger than an upper limit of the correction management range; and update the threshold range based on the plurality of updated reference data points.

The measurement data points are compared with the threshold range for each time segment during the polishing time of the workpiece, and the processing system can determine whether the measurement spectrum is normal or not based on the comparison result. Since the threshold range is determined for each time segment, the polishing of the workpiece can be stopped at a point when the measurement data points are significantly out of the threshold range. As a result, over-polishing of the workpiece can be prevented. Furthermore, damage to a subsequent workpiece caused by an incorrect polishing process can be prevented. The workpiece may be re-polished under different polishing conditions, or the workpiece may be removed from the polishing apparatus without being re-polished. As a result, a response time after the abnormality detection can be shortened. If the abnormality in the measurement spectrum is caused by the optical-film thickness measuring device, the optical-film thickness measuring device can be repaired.

### BRIEF DESCRIPTION OF THE DRAWINGS

FIG. 1 is a schematic diagram showing an embodiment of a polishing apparatus;

FIG. 2 is a cross-sectional view showing a detailed configuration of an optical film-thickness measuring device;

FIG. 3 is a schematic diagram showing an example of a measurement spectrum generated from light-intensity measurement data;

FIG. 4 is a diagram showing an example of film-thickness measurement points of light on a workpiece;

FIG. 5 is a diagram showing an embodiment of data mapping;

FIG. 6 is a diagram showing a plurality of measurement data points MD_{N} acquired during Nth rotation of a polishing table;

FIG. 7 is a diagram showing a plurality of measurement data points MD_{N+1} acquired during N+1th rotation of the polishing table;

FIG. 8 is a diagram showing a plurality of measurement data points MD_{N+2} acquired during N+2th rotation of the polishing table;

FIG. 9 is a diagram showing an embodiment in which the plurality of measurement data points MD_{N+2} are moved until the plurality of measurement data points MD_{N+2} fall within a threshold range TR_{N+2};

FIG. 10 is a diagram showing an example in which all or most of a plurality of measurement data points MD_{N+3} are outside a threshold range TR_{N+3};

FIG. 11 is a flow chart of the embodiment described with reference to FIGS. 1 to 10;

FIG. 12 is a diagram showing an embodiment in which a first set and a second set of threshold ranges are provided;

FIG. 13 is a graph showing an example of temporal transition of measurement data points plotted on a coordinate system during polishing of a workpiece;

FIG. 14 is a flow chart of the embodiment described with reference to FIGS. 12 and 13;

FIG. 15 is a graph showing an embodiment of creating a new threshold range during polishing of a workpiece;

FIG. 16 is a diagram showing an embodiment of creating a first threshold range and a second threshold range from reference data points obtained during polishing of a first reference workpiece and a second reference workpiece;

FIG. 17 is a top view showing an example of a positional relationship between an optical sensor head and a polishing head;

FIG. 18 is a diagram showing an embodiment of creating a plurality of threshold ranges corresponding to different time segments by combining the first threshold range and the second threshold range;

FIG. 19 is a top view showing an embodiment of a polishing apparatus including a first optical sensor head and a second optical sensor head;

FIG. 20 is a diagram showing an example of a plurality of first threshold ranges created from multiple reference data points obtained by light irradiation from a first optical sensor head, and a plurality of second threshold ranges created from multiple reference data points obtained by light irradiation from a second optical sensor head;

FIG. 21 is a diagram showing the plurality of first threshold ranges and the plurality of second threshold ranges arranged along a time axis; and

FIG. 22 is a diagram showing the plurality of first threshold ranges and the plurality of second threshold ranges moved along a feature axis.

### DESCRIPTION OF EMBODIMENTS

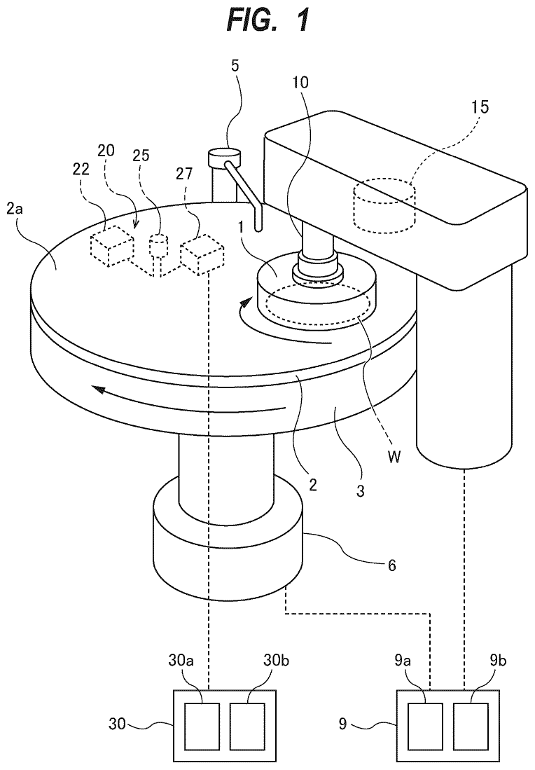

Embodiments of the present invention will be described with reference to the drawings. FIG. 1 is a schematic diagram showing an embodiment of a polishing apparatus. As shown in FIG. 1, the polishing apparatus includes a polishing table 3 configured to support a polishing pad 2 thereon, a polishing head 1 configured to press a workpiece W against the polishing pad 2, a table motor 6 configured to rotate the polishing table 3, a polishing-liquid supply nozzle 5 configured to supply a polishing liquid, such as slurry, onto the polishing pad 2, and an operation controller 9 configured to control operations of the polishing apparatus. The polishing pad 2 has an upper surface constituting a polishing surface 2a for polishing the workpiece W. The workpiece W has a film constituting an interconnect structure on a surface of the workpiece W. Examples of the workpiece W include a wafer, a substrate, an interconnect substrate, a quadrangular substrate, or the like for use in manufacturing of semiconductor devices. In one example, the workpiece W is a product wafer on which a multilayer film or single film is formed.

The polishing head 1 is coupled to a head shaft 10, and the head shaft 10 is coupled to a polishing-head rotating device 15. The polishing-head rotating device 15 is configured to rotate the polishing head 1 together with the head shaft 10 in a direction indicated by an arrow. The configuration of the polishing-head rotating device 15 is not particularly limited. In an example, the polishing-head rotating device 15 includes an electric motor, a belt, and pulleys. The polishing table 3 is coupled to the table motor 6, and the table motor 6 is configured to rotate the polishing table 3 and the polishing pad 2 in a direction indicated by an arrow. The polishing head 1, the polishing-head rotating device 15, and the table motor 6 are electrically coupled to the operation controller 9.

Polishing of the workpiece W is performed as follows. The polishing liquid is supplied from the polishing-liquid supply nozzle 5 onto the polishing surface 2a of the polishing pad 2 on the polishing table 3, while the table motor 6 and the polishing-head rotating device 15 rotate the polishing table 3 and the polishing head 1 in the directions indicated by the arrows in FIG. 1. The workpiece W is pressed against the polishing surface 2a of the polishing pad 2 by the polishing head 1 in the presence of the polishing liquid on the polishing pad 2, while the workpiece W is being rotated by the polishing head 1. The surface of the workpiece W is polished by a chemical action of the polishing liquid and mechanical action(s) of abrasive grains contained in the polishing liquid and/or the polishing pad 2.

The operation controller 9 includes a memory 9a storing programs therein, and an arithmetic device 9b configured to perform arithmetic operations according to instructions contained in the programs. The operation controller 9 is composed of at least one computer. The memory 9a includes a main memory, such as a random-access memory (RAM), and an auxiliary memory, such as a hard disk drive (HDD) or a solid state drive (SSD). Examples of the arithmetic device 9b include a CPU (central processing unit) and a GPU (graphic processing unit). However, the specific configuration of the operation controller 9 is not limited to these examples.

The polishing apparatus includes an optical film-thickness measuring device 20 for measuring a film thickness of the workpiece W. The optical film-thickness measuring device 20 includes a light source 22 configured to emit light, an optical sensor head 25 configured to irradiate the workpiece W with the light from the light source 22 and receive reflected light from the workpiece W, a spectrometer 27 coupled to the optical sensor head 25, and a processing system 30 configured to determine a film thickness of the workpiece W based on a spectrum of the reflected light from the workpiece W. The optical sensor head 25 is disposed within the polishing table 3 and rotates together with the polishing table 3.

The processing system 30 includes a memory 30a storing programs therein, and an arithmetic device 30b configured to perform arithmetic operations according to instructions contained in the programs. The processing system 30 is composed of at least one computer. The memory 30a includes a main memory, such as a random-access memory (RAM), and an auxiliary memory, such as a hard disk drive (HDD) or a solid state drive (SSD). Examples of the arithmetic device 30b include a CPU (central processing unit) and a GPU (graphic processing unit). However, the specific configuration of the processing system 30 is not limited to these examples.

Each of the operation controller 9 and the processing system 30 may be composed of a plurality of computers. For example, each of the operation controller 9 and the processing system 30 may be configured of a combination of an edge server and a cloud server. In one embodiment, the operation controller 9 and the processing system 30 may be comprised of one computer.

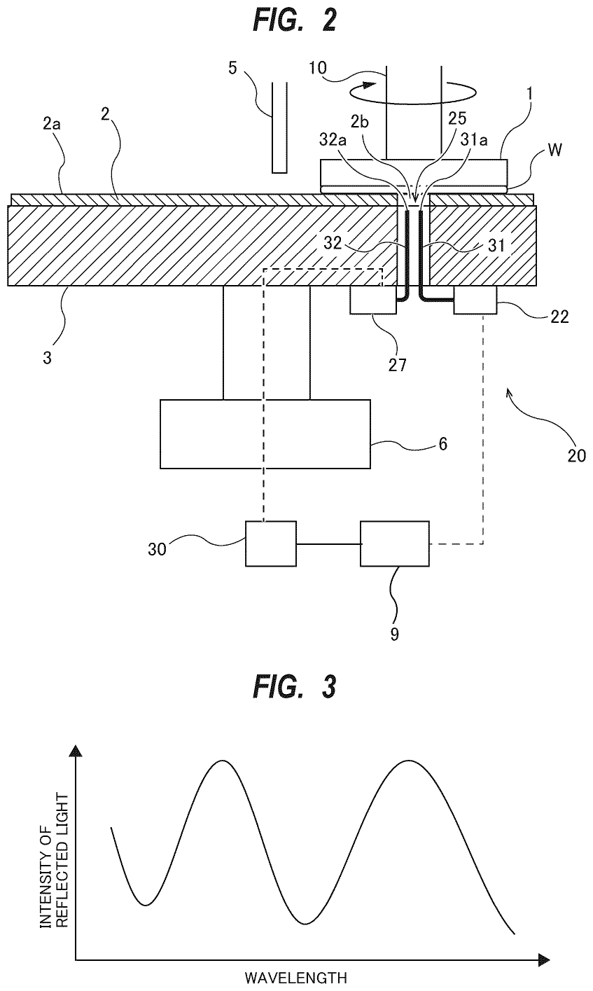

FIG. 2 is a cross-sectional view showing a detailed configuration of the optical film-thickness measuring device 20. The optical film-thickness measuring device 20 includes a light-emitting optical fiber cable 31 coupled to the light source 22 and a light-receiving optical fiber cable 32 coupled to the spectrometer 27. A distal end 31a of the light-emitting optical fiber cable 31 and a distal end 32a of the light-receiving optical fiber cable 32 constitute the optical sensor head 25. Specifically, the light-emitting optical fiber cable 31 directs the light, emitted by the light source 22, to the workpiece W on the polishing pad 2, and the light-receiving optical fiber cable 32 receives the reflected light from the workpiece W and transmits the reflected light to the spectrometer 27.

The spectrometer 27 is coupled to the processing system 30. The light-emitting optical fiber cable 31, the light-receiving optical fiber cable 32, the light source 22, and the spectrometer 27 are attached to the polishing table 3 and rotate together with the polishing table 3 and the polishing pad 2. The optical sensor head 25, which is composed of the distal end 31a of the light-emitting optical fiber cable 31 and the distal end 32a of the light-receiving optical fiber cable 32, is disposed facing the surface of the workpiece W on the polishing pad 2.

The optical sensor head 25 is arranged such that the optical sensor head 25 sweeps across the surface of the workpiece W on the polishing pad 2 each time the polishing table 3 and polishing pad 2 make one rotation. The polishing pad 2 has a through-hole 2b located above the optical sensor head 25. The optical sensor head 25 irradiates the light onto the workpiece W through the through-hole 2b each time the polishing table 3 makes one rotation, and receives the reflected light from the workpiece W through the through-hole 2b.

In one embodiment, a flow of pure water may be formed in the through-hole 2b of the polishing pad 2 so as to prevent the polishing liquid and polishing debris from contacting the optical sensor head 25. The light is directed from the optical sensor head 25 through the pure water to the workpiece W, and the reflected light from the workpiece W is received by the optical sensor head 25 through the pure water. In another embodiment, a transparent window (not shown) may be fitted in the through-hole 2b of the polishing pad 2. The transparent window is made of a material (e.g., transparent resin) that allows the light to pass therethrough. In this case, the light is directed from the optical sensor head 25 through the transparent window to the workpiece W, and the reflected light from the workpiece W is received by the optical sensor head 25 through the transparent window.

The light source 22 may be a flash light source that repeatedly emits the light at short time intervals. An example of the light source 22 is a xenon flash lamp. The light source 22 is electrically coupled to the operation controller 9, and emits the light upon receiving a trigger signal sent from the operation controller 9. More specifically, when the optical sensor head 25 is moving across the surface of the workpiece W on the polishing pad 2, the light source 22 receives multiple trigger signals and emits the light multiple times. Therefore, each time the polishing table 3 makes one rotation, the light is directed to a plurality of film-thickness measurement points on the workpiece W.

The light emitted by the light source 22 is transmitted to the optical sensor head 25. Specifically, the light is transmitted to the optical sensor head 25 through the light-emitting optical fiber cable 31 and is emitted from the optical sensor head 25. The light travels through the through-hole 2b of the polishing pad 2 and is incident on the workpiece W on the polishing pad 2. The reflected light from the workpiece W travels through the through-hole 2b of the polishing pad 2 again and is received by the optical sensor head 25. The reflected light from the workpiece W is transmitted to the spectrometer 27 through the light-receiving optical fiber cable 32.

The spectrometer 27 is configured to resolve the reflected light according to wavelength and measure intensity of the reflected light at each of wavelengths of the reflected light over a predetermined wavelength range. Specifically, the spectrometer 27 resolves the reflected light from the workpiece W according to wavelength and measures the intensity of the reflected light at each of the wavelengths over a predetermined wavelength range to generate light-intensity measurement data. The intensity of the reflected light at each wavelength may be expressed as a relative value, such as reflectance or relative reflectance. The light-intensity measurement data is sent to the processing system 30.

The processing system 30 generates a spectrum of the reflected light as shown in FIG. 3 from the light-intensity measurement data. In the following descriptions, the spectrum of the reflected light from the workpiece W is referred to as measurement spectrum. The measurement spectrum of the reflected light from the workpiece W includes information on the film thickness of the workpiece W. In other words, the measurement spectrum of the reflected light varies depending on the film thickness of the workpiece W. The processing system 30 is configured to determine the film thickness of the workpiece W based on the measurement spectrum of the reflected light. For example, the processing system 30 determines, from a reference-spectrum library, a reference spectrum having a shape closest to a shape of the measurement spectrum of the reflected light, and determines a film thickness associated with the determined reference spectrum. In another example, the processing system 30 calculates a feature of the measurement spectrum of the reflected light, determines a reference feature that is closest to that feature from a reference feature library, and determines a film thickness associated with the determined reference feature. In another example, the processing system 30 performs a Fourier transform on the measurement spectrum of the reflected light and determines a film thickness from a resulting frequency spectrum.

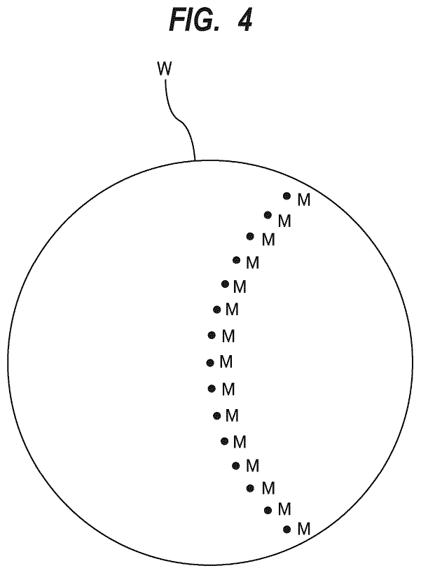

FIG. 4 is a diagram showing an example of a plurality of film-thickness measurement points on the workpiece W. As described above, during polishing of the workpiece W, the optical sensor head 25 irradiates the surface of the workpiece W with the light multiple times while moving across the surface of the workpiece W in each rotation of the polishing table 3. Thus, as shown in FIG. 4, a plurality of film-thickness measurement points M irradiated with the light from the optical sensor head 25 are aligned in a radial direction on the surface of the workpiece W. Each time the polishing table 3 make one rotation, the optical sensor head 25 receives the reflected light from the plurality of film-thickness measurement points M, and the processing system 30 generates a plurality of measurement spectra of the reflected light from the plurality of film-thickness measurement points M. Furthermore, the processing system 30 determines a plurality of film thicknesses at the plurality of film-thickness measurement points M from the plurality of measurement spectra of the reflected light.

The film thickness of the workpiece W varies depending on the measurement spectrum of the reflected light. Therefore, in order for the optical film-thickness measuring device 20 to accurately measure the film thickness of the workpiece W, it is necessary to acquire an accurate measurement spectrum that reflects the film thickness. However, the measurement spectrum may change due to failure or aging of optical elements, such as the light source 22 or the optical fiber cables 31 and 32.

Thus, the processing system 30 inspects the measurement spectrum of the reflected light from the workpiece W, as described below. First, a reference workpiece having the same surface structure as that of the workpiece W is polished by the polishing apparatus shown in FIGS. 1 and 2. The reference workpiece is polished under the same polishing conditions as those for the workpiece W. The polishing conditions include a rotation speed of the polishing table 3, a rotation speed of the polishing head 1, a supply flow rate of the polishing liquid, a pressing pressure of the polishing head 1 against the workpiece W, etc.

The processing system 30 generates a spectrum of reflected light from the reference workpiece according to the method described with reference to FIGS. 1 to 4. In the following descriptions, the spectrum of reflected light from the reference workpiece is referred to as reference spectrum. As described with reference to FIG. 4, each time the polishing table 3 makes one rotation, the light is directed to a plurality of film-thickness measurement points on the reference workpiece, and a plurality of reference spectra of reflected light from the plurality of film-thickness measurement points are generated.

The processing system 30 calculates a feature of each of the plurality of reference spectra. The feature is an index representing characteristics of each reference spectrum. More specifically, each reference spectrum is indicative of intensity of the reflected light at each wavelength as shown in FIG. 3, and therefore, the feature is an index representing characteristics of intensity of the reflected light at each wavelength of the reference spectrum.

In this embodiment, the processing system 30 performs principal component analysis on a data set including a plurality of intensities of the reflected light at a plurality of wavelengths of each reference spectrum, and determines a feature including at least a k-th principal component (k is a natural number) obtained from the principal component analysis. An example of a calculation formula for the k-th principal component is as follows:

k-th principal component=wₖ₁X1+wₖ₂X2+wₖ₂X3+ . . .
where Xn (n is a natural number) represents intensity of the reflected light at a wavelength λn of the reference spectrum, and wₖₙ is a weight coefficient for the intensity Xn.

The processing system 30 calculates at least one feature for each reference spectrum. For example, the processing system 30 calculates the k-th principal component as the feature for each reference spectrum. In another example, the processing system 30 may calculate k-th principal component and k+1-th principal component as the feature for each reference spectrum. In this embodiment, the feature is the k-th principal component (k is a natural number) obtained by the principal component analysis of the data set. In another embodiment, the feature may be a statistical value of the data set (e.g., mean, standard deviation, variance, etc.).

The optical sensor head 25 emits the light to the plurality of film-thickness measurement points on the reference workpiece and receives the reflected light from the plurality of film-thickness measurement points in each time segment within the polishing time of the reference workpiece. In one embodiment, the time segment is a time for the polishing table 3 to make L rotation(s) (L is a natural number). Specifically, each time the polishing table 3 makes the L rotation, the optical sensor head 25 emits the light to the plurality of film-thickness measurement points on the reference workpiece and receives the reflected light from the plurality of film-thickness measurement points. The processing system 30 generates a plurality of reference spectra of the reflected light from the plurality of film-thickness measurement points on the reference workpiece and calculates a plurality of features from the plurality of reference spectra, each time the polishing table 3 makes the L rotation. Thus, the plurality of features are obtained in each L rotation of the polishing table 3. In another embodiment, the time segment may be defined by time. For example, the time segment may be defined by second which is time unit (e.g., 0.5 seconds, 1 second, or 1.5 seconds).

The processing system 30 associates the plurality of features with a plurality of times at which the plurality of reference spectra were generated, respectively. Since each feature is calculated from a corresponding reference spectrum, each feature can be associated with a time at which the corresponding reference spectrum was generated. The time at which the reference spectrum was generated is not particularly limited as long as that time directly or indirectly indicates a time at which the reference spectrum was generated by the processing system 30. For example, the time at which the reference spectrum was generated may be represented by a time at which the light for generating the reference spectrum was emitted from the light source 22, or a time at which the spectrometer 27 received the reflected light for generating the reference spectrum, or a time at which the processing system 30 received the light-intensity measurement data for generating the reference spectrum, or a time linked to a time at which the reference spectrum was generated by the processing system 30.

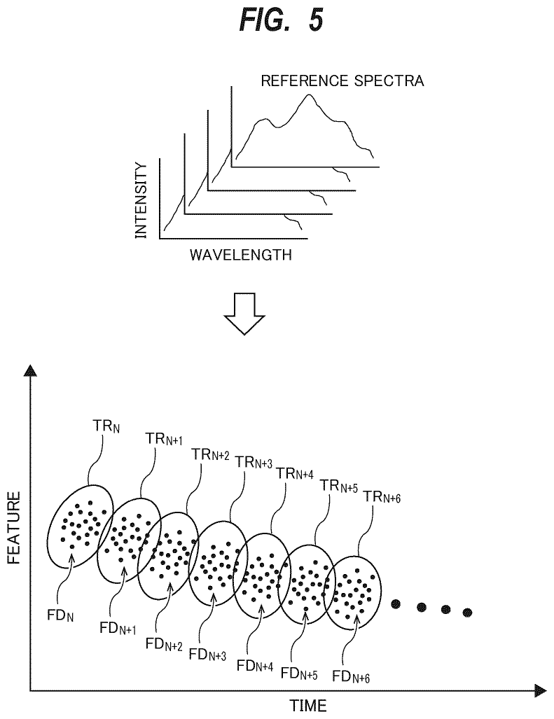

The processing system 30 performs data mapping by plotting a plurality of reference data points on a coordinate system. The plurality of reference data points are specified or determined by the plurality of times at which the plurality of reference spectra were generated and the plurality of features corresponding to the plurality of times. FIG. 5 is a diagram showing an embodiment of the data mapping. As shown in FIG. 5, the coordinate system has a vertical axis representing the feature of the reference spectrum and a horizontal axis representing time.

The processing system 30 generates the plurality of reference spectra of the reflected light from the plurality of film-thickness measurement points on the reference workpiece for each time segment during the polishing time of the reference workpiece, and calculates a plurality of features of the plurality of reference spectra. In the embodiment described below, the time segment is a time of one rotation of the polishing table 3. Each time the polishing table 3 makes one rotation, the processing system 30 plots, on the coordinate system, the plurality of reference data points specified or determined by the plurality of features of the plurality of reference spectra and the plurality of corresponding times.

FD_{N} shown in FIG. 5 represents a plurality of reference data points acquired when the polishing table 3 makes an Nth rotation (N is a natural number), FD_{N+1} represents a plurality of reference data points acquired when the polishing table 3 makes an N+1th rotation, and FD_{N+2} represents a plurality of reference data points acquired when the polishing table 3 makes an N+2th rotation. As can be seen from FIG. 5, the number of reference data points increases with the polishing time of the reference workpiece. In the following description, each of the reference data points FD_{N}, FD_{N+1}, FD_{N+2}, . . . may be simply referred to as a reference data point FD.

The processing system 30 determines a threshold range for each time segment. The threshold range is a dispersion allowable range of the plurality of reference data points and is determined on the coordinate system for each time segment. All or most of the plurality of reference data points FD acquired in each time segment are located within the corresponding threshold range. In one embodiment, a predetermined rate (%) of the plurality of reference data points FD are within the corresponding threshold range. The predetermined rate (%) is, for example, within a range of 90 to 100%.

In the example shown in FIG. 5, a threshold range TR_{N} is determined from the plurality of reference data points FD_{N}, a threshold range TR_{N+1} is determined from the plurality of reference data points FD_{N+1}, and a threshold range TR_{N+2} is determined from the plurality of reference data points FD_{N+2}. In the same manner, the processing system 30 determines a plurality of threshold ranges corresponding to the plurality of time segments. In the following description, each of the threshold ranges TR_{N}, TR_{N+1}, TR_{N+2}, . . . may be simply referred to as threshold range TR.

In one embodiment, each threshold range TR is a range within a predetermined Mahalanobis distance from a datum point determined from the plurality of reference data points FD in a corresponding time segment. The predetermined Mahalanobis distance is a distance within which a predetermined rate (%) of the plurality of reference data points FD exist within the corresponding threshold range TR.

In another embodiment, each threshold range TR is a range within a predetermined Euclidean distance from a datum point determined from the plurality of reference data points FD in a corresponding time segment. The predetermined Euclidean distance is a distance within which a predetermined rate (%) of the plurality of reference data points FD exist within the corresponding threshold range TR. In yet another embodiment, each threshold range TR may be a range determined based on a standard deviation or variance calculated from a normal distribution of the plurality of reference data points FD in the corresponding time segment.

An example of the datum point is a center of gravity of the plurality of reference data points FD in the time segment corresponding to each threshold range TR. In one example, the center of gravity of the plurality of reference data points FD may be obtained by multiplying distances of the plurality of reference data points FD from a virtual center of gravity of the plurality of reference data points FD by weight coefficients that vary according to those distances. The processing system 30 stores the plurality of threshold ranges TR corresponding to the plurality of time segments in the memory 30a.

In the above embodiment, the plurality of threshold ranges TR are determined from the plurality of reference data points obtained during polishing of one reference workpiece. In one embodiment, a plurality of reference workpieces may be polished in the same manner, and the plurality of threshold ranges TR corresponding to the plurality of time segments may be determined from reference data points obtained during polishing of these reference workpieces.

The processing system 30 inspects the measurement spectrum of the reflected light generated during polishing of the workpiece W using the threshold range TR. Polishing of the workpiece W and generation of the measurement spectrum of the reflected light from the workpiece W are performed in the same manner as those for the reference workpiece. Specifically, while the polishing table 3 is rotated by the table motor 6, the polishing head 1 presses the workpiece W against the polishing pad 2 on the polishing table 3 to polish the workpiece W. The optical sensor head 25 emits the light to the plurality of film-thickness measurement points on the workpiece W in each of the time segments during polishing of the workpiece W and receives the reflected light from the plurality of film-thickness measurement points. In one example, each time segment corresponds to a time of one rotation of the polishing table 3.

The processing system 30 generates the plurality of measurement spectra of the reflected light from the plurality of film-thickness measurement points, and calculates a plurality of features of the plurality of measurement spectra. The features of the plurality of measurement spectra are calculated in the same manner as the features of the plurality of reference spectra. Specifically, the processing system 30 calculates the k-th principal component (k is a natural number) by performing the principal component analysis on a data set including a plurality of intensities of the reflected light at a plurality of wavelengths of each measurement spectrum, and determines a feature including at least the k-th principal component for each measurement spectrum. The feature of each measurement spectrum are the same type of index as the feature of the reference spectrum. Specifically, when the feature of the reference spectrum includes only the k-th principal component, the feature of the measurement spectrum also includes only the k-th principal component. When the feature of the reference spectrum includes the k-th principal component and the k+1-th principal component, the feature of the measurement spectrum also includes the k-th principal component and the k+1-th principal component.

The processing system 30 performs data mapping by plotting, on the coordinate system, measurement data points specified or determined by a plurality of times at which the plurality of measurement spectra were generated and the plurality of features, in the same manner as the data mapping performed for the reference spectra.

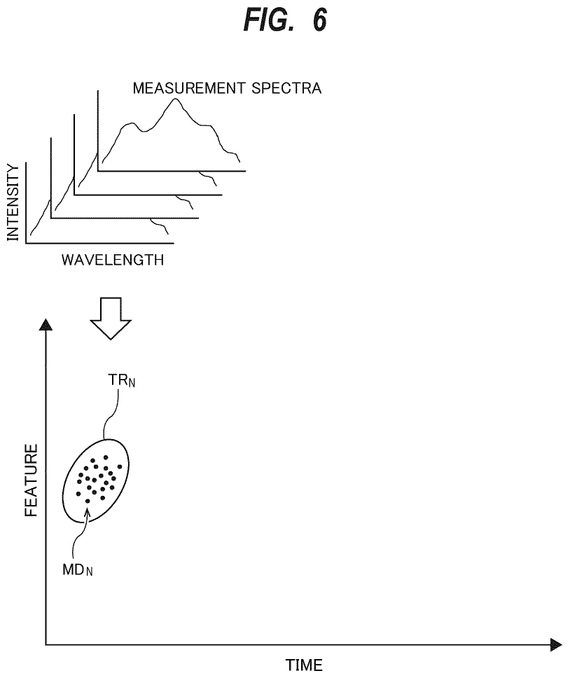

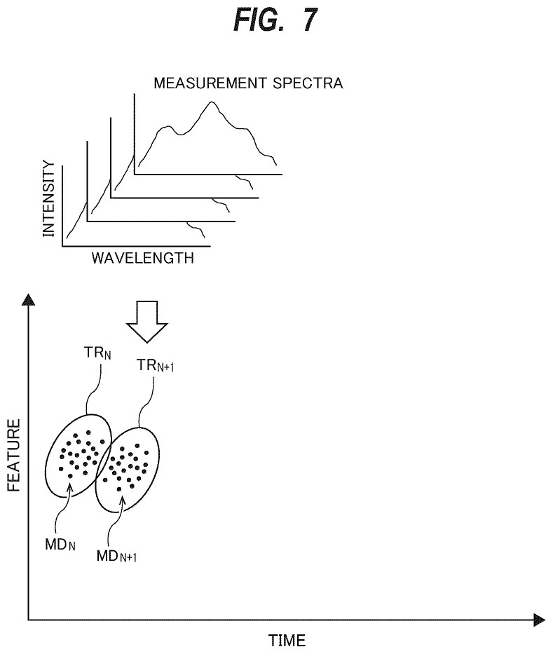

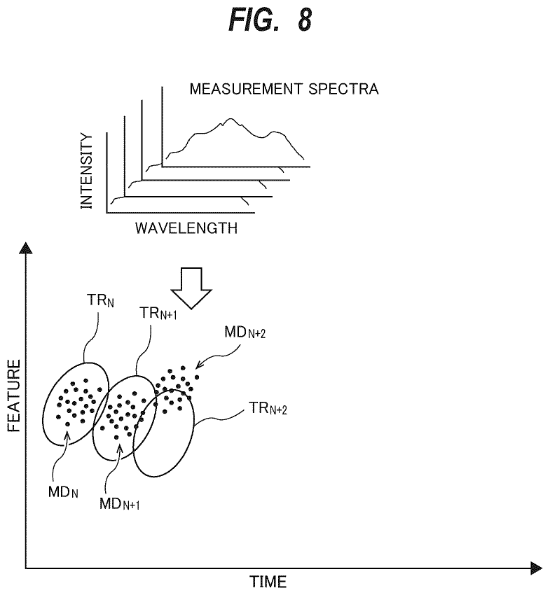

FIG. 6 is a diagram showing a plurality of measurement data points MD_{N} acquired when the polishing table 3 makes an Nth rotation, FIG. 7 is a diagram showing a plurality of measurement data points MD_{N+1} acquired when the polishing table 3 makes an N+1th rotation, and FIG. 8 is a diagram showing a plurality of measurement data points MD_{N+2} acquired when the polishing table 3 makes an N+2th rotation. In the following description, each of the measurement data points MD_{N}, MD_{N+1}, MD_{N+2}, . . . may be simply referred to as measurement data point MD. As shown in FIGS. 6 to 8, the processing system 30 plots the plurality of measurement data points MD on the coordinate system each time the polishing table 3 makes one rotation. The coordinate system has vertical axis representing feature and horizontal axis representing time.

The processing system 30 determines a correction index value that indicates the number of measurement data points MD that exist within the threshold range TR defined on the coordinate system for each time segment. This correction index value is an index that indicates a degree to which the plurality of measurement data points MD exist within the threshold range TR.

Examples of the correction index value include the followings.
The number of measurement data points that exist within the threshold range
A ratio of the number of measurement data points that exist within the threshold range to the total number of measurement data points
A distance between the center of gravity of the plurality of measurement data points and the center of the threshold range

In the embodiment described below, the correction index value is a ratio of the number of measurement data points MD present within the threshold range TR to the total number of measurement data points MD. In the example shown in FIG. 6, the processing system 30 calculates a ratio of the number of measurement data points MD_{N} present within the threshold range TR_{N} corresponding to the time segment in which the measurement data points MD_{N} were acquired to the total number of measurement data points MD_{N}, and determines the correction index value that is the calculated ratio.

In this embodiment, the correction index value is the ratio of the plurality of measurement data points MD that are present within the threshold range TR. For example, if the calculated correction index value is 100%, all of the plurality of measurement data points MD are present within the threshold range TR. If the calculated correction index value is 50%, half of the plurality of measurement data points MD are present within the threshold range TR. The processing system 30 determines whether the correction index value is within a predetermined correction management range. The correction management range is a numerical range for determining whether to correct the measurement spectrum, or to use the measurement spectrum for film thickness measurement without correcting it, or to generate an alarm signal, as described later. For example, the correction management range is 20 to 80%.

In the example shown in FIG. 6, the processing system 30 determines that the correction index value, which is the ratio of the number of measurement data points MD_{N} present within the threshold range TR_{N} to the total number of measurement data points MD_{N}, is larger than an upper limit of the correction management range. The fact that the correction index value is larger than the upper limit of the correction management range means that all or most of the measurement data points MD_{N} are present within the threshold range TR_{N}. Therefore, when the correction index value is larger than the upper limit of the correction management range, the processing system 30 determines that the measurement spectra corresponding to the measurement data points MD_{N} are normal, and determines (or estimates) the film thicknesses at the film-thickness measurement points on the workpiece W from the measurement spectra.

The measurement data points MD_{N} shown in FIG. 6 indicate that the corresponding measurement spectra are normal. Therefore, the measurement data points MD_{N} can be used to update the threshold range TR_{N}. Specifically, when the correction index value is larger than the upper limit of the correction management range, the processing system 30 updates the reference data points FD_{N} by adding the measurement data points MD_{N} to the reference data points FD_{N} (see FIG. 5), and updates the threshold range TR_{N} based on the updated reference data points FD_{N}. Since the number of reference data points FD_{N} used to determine the threshold range TR_{N} increases, the processing system 30 can determine a more accurate threshold range TR.

In the example shown in FIG. 7, the processing system 30 determines that the correction index value, which is the ratio of the number of measurement data points MD_{N+1} present within the threshold range TR_{N+1} to the total number of measurement data points MD_{N+1}, is larger than the upper limit of the correction management range. Therefore, the processing system 30 determines that the measurement spectra corresponding to the measurement data points MD_{N+1} are normal, and determines (or estimates) the film thicknesses at the film-thickness measurement points on the workpiece W from those measurement spectra. Since the measurement data points MD_{N+1} shown in FIG. 7 indicate that the corresponding measurement spectra are normal, the measurement data points MD_{N+1} can be used to update the threshold range TR_{N+1}.

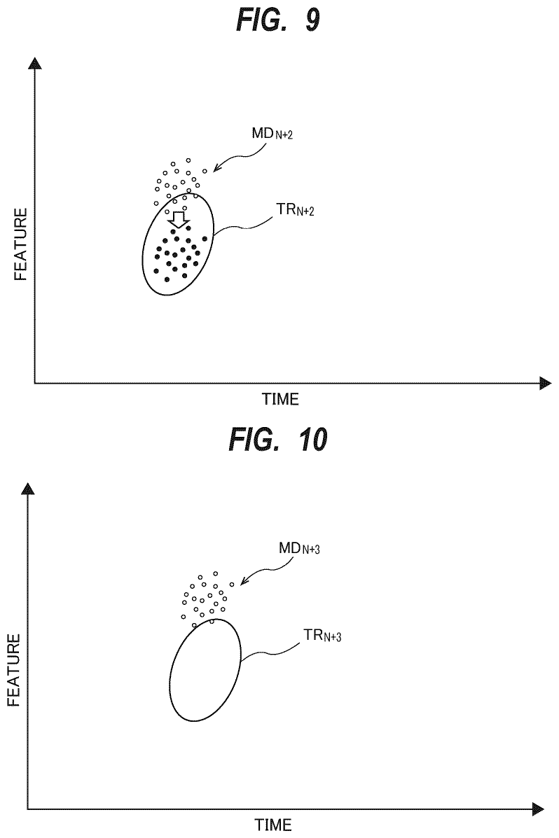

In the example shown in FIG. 8, the processing system 30 determines that the correction index value, which is the ratio of the number of measurement data points MD_{N+2} existing within the threshold range TR_{N+2} to the total number of measurement data points MD_{N+2}, is within the correction management range. When the correction index value is within the correction management range, as shown in FIG. 9, the processing system 30 corrects the features specified by the measurement data points MD_{N+2} by moving the measurement data points MD_{N+2} on the coordinate system until the measurement data points MD_{N+2} fall within the threshold range TR_{N+2}. Examples of the movement of the measurement data points MD_{N+2} include translation, rotation, and reduction.

In one embodiment, the processing system 30 converts the features corrected by the movement of the measurement data points MD_{N+2} into corrected measurement spectra. In this embodiment, the feature of each measurement data point MD_{N+2} is the k-th principal component obtained by the principal component analysis, so that the k-th principal component can be restored to a format of the original data set. Specifically, the processing system 30 converts each corrected feature into multiple intensities of the reflected light at multiple wavelengths, and creates a corrected measurement spectrum from the converted multiple intensities and the corresponding multiple wavelengths. Since the corrected measurement spectrum is created from the measurement data point that is present within the threshold range TR_{N+2}, the processing system 30 can determine an accurate film thickness from the corrected measurement spectrum.

In this embodiment, the feature is the k-th principal component (k is a natural number) obtained by the principal component analysis of the data set. In another embodiment, the feature may be a statistical value of the data set (e.g., mean, standard deviation, variance, etc.). When the feature is an average of the plurality of intensities included in the data set, the plurality of intensities are corrected by subtracting an intensity, which corresponds to an amount of movement of the measurement data point to the threshold range TR, from each of the plurality of intensities of the reflected light at the plurality of wavelengths, and a corrected measurement spectrum is created from the corrected plurality of intensities and the corresponding plurality of wavelengths.

In one embodiment, the processing system 30 may calculate the film thickness of the workpiece W from the corrected feature without creating the corrected measurement spectrum. For example, the processing system 30 determines, from a reference feature library, a reference feature that is closest to the corrected feature, and determines a film thickness associated with the determined reference feature. The reference feature library includes a plurality of reference features and a plurality of corresponding film thicknesses.

In an example shown in FIG. 10, the processing system 30 determines that the correction index value, which is the ratio of the number of measurement data points MD_{N+3} existing within the threshold range TR_{N+3} to the total number of measurement data points MD_{N+3}, is smaller than a lower limit of the correction management range. The correction index value being smaller than the lower limit of the correction management range means that all or most of the multiple measurement data points MD_{N+3} are outside the threshold range TR_{N+3}. Therefore, when the correction index value is smaller than the lower limit of the correction management range, the processing system 30 generates an alarm signal indicating an abnormality in the measurement spectra corresponding to the measurement data points MD_{N+3}.

In one embodiment, the processing system 30 may transmit the alarm signal to the operation controller 9. Upon receiving the alarm signal, the operation controller 9 may instruct the polishing apparatus to terminate polishing of the workpiece W. The operation controller 9 may instruct the polishing apparatus to perform re-polishing of the workpiece W. In another embodiment, the processing system 30 may transmit the alarm signal to a host computer that manages the polishing apparatus. The alarm signal transmitted to the host computer can prompt a management person to inspect or repair the polishing apparatus.

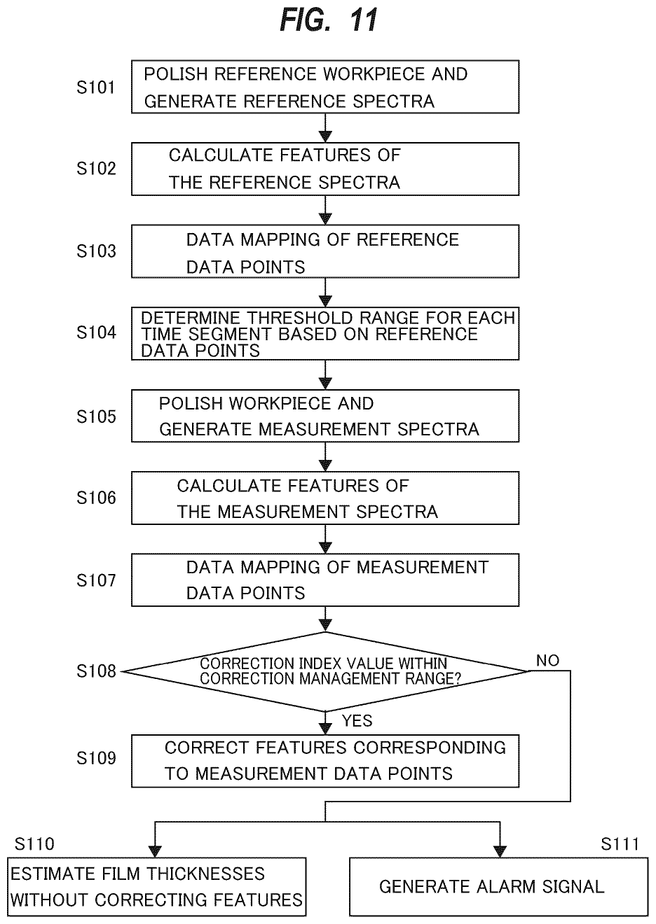

FIG. 11 is a flowchart of the embodiment described with reference to FIGS. 1 to 10.

In step S101, the reference workpiece is pressed against the polishing pad 2 on the polishing table 3 while the polishing table 3 is rotating, so that the reference workpiece is polished. In each of the time segments within the polishing time of the reference workpiece, the optical sensor head 25 emits the light to the plurality of film-thickness measurement points on the reference workpiece, and the processing system 30 generates the plurality of reference spectra of the reflected light from the plurality of film-thickness measurement points.

The plurality of film-thickness measurement points of the reference workpiece are distributed over the entire surface of the reference workpiece. Device regions and scribe lines coexist in a surface of the reference workpiece. The reflected light from the scribe lines is significantly different from the reflected light from the device regions and may be noise for film thickness measurement. Therefore, in one embodiment, the processing system 30 may apply a filter to the plurality of reference spectra generated during polishing of the reference workpiece to remove reference spectra that may be noise.

In step S102, the processing system 30 calculates the plurality of features of the plurality of reference spectra. At least one feature is calculated for each reference spectrum. Examples of feature include the kth principal component (k is a natural number) obtained by the principal component analysis, and statistical value (e.g., average).

In step S103, the processing system 30 performs data mapping by plotting, on the coordinate system, a plurality of reference data points FD specified or determined by a plurality of times at which the plurality of reference spectra were generated and the plurality of corresponding features (see FIG. 5).

In step S104, the processing system 30 determines the threshold range TR for each of the time segments within the polishing time of the reference workpiece based on the plurality of reference data points FD on the coordinate system (see FIG. 5). In one embodiment, each time segment is a time for one rotation of the polishing table 3. The plurality of threshold ranges TR corresponding to the plurality of time segments are determined. In one embodiment, each threshold range TR is a range within a predetermined Mahalanobis distance from a datum point that is predetermined based on the plurality of reference data points FD within the corresponding time segment.

In step S105, the workpiece W is pressed against the polishing pad 2 on the polishing table 3 while the polishing table 3 is rotating, so that the workpiece W is polished. In each of the time segments during polishing of the workpiece W, the optical sensor head 25 emits the light onto the plurality of film-thickness measurement points on the workpiece W, and the processing system 30 generates a plurality of measurement spectra of the reflected light from the plurality of film-thickness measurement points. In one embodiment, the processing system 30 may perform filtering on the plurality of measurement spectra generated during polishing of the workpiece W to remove measurement spectra that may be noise.

In step S106, the processing system 30 calculates the plurality of features of the plurality of measurement spectra. The features of the plurality of measurement spectra are calculated in the same manner as the features of the plurality of reference spectra calculated in the step S102.

In step S107, the processing system 30 performs data mapping by plotting, on the coordinate system, a plurality of measurement data points MD specified or determined by a plurality of times at which the plurality of measurement spectra were generated and the plurality of features of the plurality of measurement spectra (see FIGS. 6, 7, and 8).

In step S108, the processing system 30 determines the correction index value representing the number of measurement data points existing within the threshold range TR defined on the coordinate system for each time segment, and determines whether the correction index value is within the correction management range. In one example, the correction index value is a ratio of the number of measurement data points existing within each threshold range TR to the total number of measurement data points. In another example, the correction index value is the number of measurement data points itself existing within each threshold range TR.

In step S109, when the correction index value is within the correction management range, the processing system 30 corrects the features corresponding to the plurality of measurement data points MD by moving the plurality of measurement data points MD on the coordinate system until the plurality of measurement data points MD fall within the corresponding threshold range TR (see FIG. 9). In one embodiment, the processing system 30 generates a plurality of corrected measurement spectra by converting the corrected features into a plurality of measurement spectra. The processing system 30 determines (or estimates) a plurality of film thicknesses at the plurality of film-thickness measurement points on the workpiece W from the plurality of corrected measurement spectra. In another embodiment, the processing system 30 determines (or estimates) a plurality of film thicknesses at the plurality of film-thickness measurement points on the workpiece W from the corrected features without generating the corrected measurement spectra.

In step S110, when the correction index value is larger than the upper limit of the correction management range, the processing system 30 determines (or estimates) a plurality of film thicknesses at the plurality of film-thickness measurement points on the workpiece W from the plurality of measurement spectra without correcting the features corresponding to the plurality of measurement data points MD.

In step S111, when the correction index value is less than the lower limit of the correction management range, the processing system 30 generates the alarm signal. The processing system 30 may send the alarm signal to the operation controller 9 to stop polishing of the workpiece W.

The change in the spectrum of the reflected light over polishing time shows different trends depending on the surface structure of the workpiece W. In particular, the spectrum of reflected light from the workpiece W may be affected not only by a top layer of the workpiece W, but also by an underlying layer. As a result, the temporal change in the measurement data points specified by the features and the times during polishing may vary depending on the surface structure of the workpiece W. In order to correctly inspect the spectrum of the reflected light from the workpiece W, it is necessary to select an appropriate threshold range based on differences in the surface structure of the workpiece W.

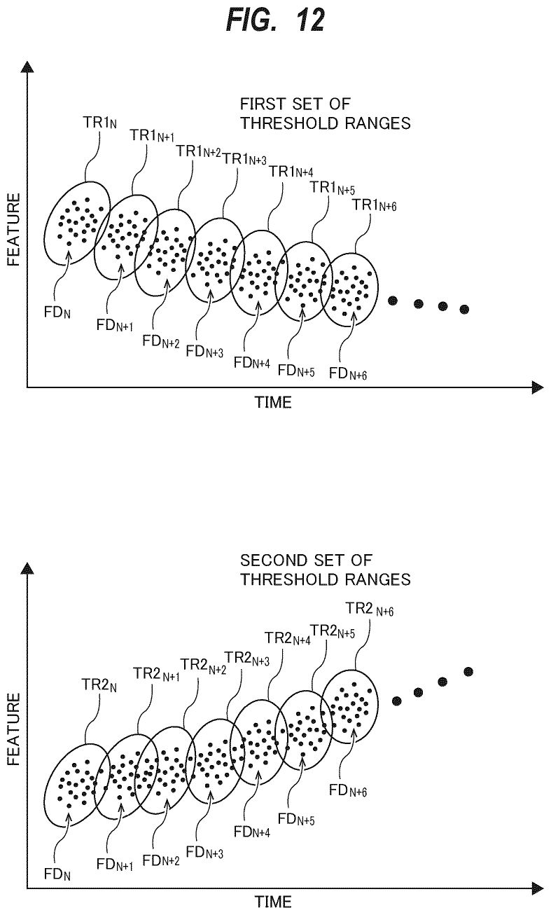

Thus, in an embodiment described below with reference to FIG. 12, the processing system 30 has a first set and a second set of threshold ranges determined from reference data points obtained during polishing of a plurality of reference workpieces having different surface structures. Details of this embodiment that are not specifically described are the same as those of the previously described embodiments, and therefore repeated description thereof will be omitted.

The first set of threshold ranges is generated from reference data points obtained during polishing of a first reference workpiece, and a second set of threshold ranges is generated from reference data points obtained during polishing of a second reference workpiece. The first and second reference workpieces are polished under the same polishing conditions as those for the workpiece W. The first and second sets of threshold ranges are generated in the same manner as the embodiment described with reference to FIG. 5.

The first and second reference workpieces have different surface structures. As a result, a trend of change in the first set of threshold ranges TR1 with polishing time is different from a trend of change in the second set of threshold ranges TR2 with polishing time, as shown in FIG. 12. In the example shown in FIG. 12, the first set of threshold ranges TR1 shows a downward trend with polishing time, and the second set of threshold ranges TR2 shows an upward trend with polishing time. The first set of threshold ranges TR1 and the second set of threshold ranges TR2 are stored in the memory 30a of the processing system 30.

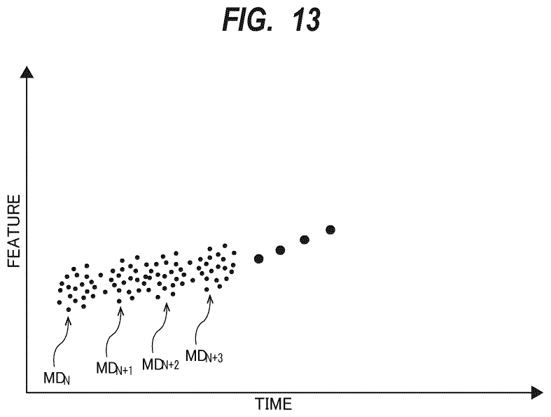

FIG. 13 is a graph showing an example of a temporal change in the plurality of measurement data points MD plotted on the coordinate system during polishing of the workpiece W. The processing system 30 selects either the first set of threshold ranges TR1 or the second set of threshold ranges TR2 shown in FIG. 12 based on the trend of change in the plurality of measurement data points MD with the polishing time of the workpiece W. In the example shown in FIG. 13, the measurement data points MD show an upward trend with the polishing time. Therefore, the processing system 30 selects the second set of threshold ranges TR2. After the second set is selected, the processing system 30 determines the correction index value representing the number of measurement data points MD existing within the threshold range TR2 defined on the coordinate system for each time segment, as in the above-mentioned embodiments, and determines whether the correction index value is within the correction management range.

In one embodiment, the processing system 30 may have three or more sets of threshold ranges obtained from reference data points obtained during polishing of three or more reference workpieces having different surface structures. The processing system 30 may select one of the three or more sets based on a trend of change in the measurement data points over the polishing time of the workpiece W.

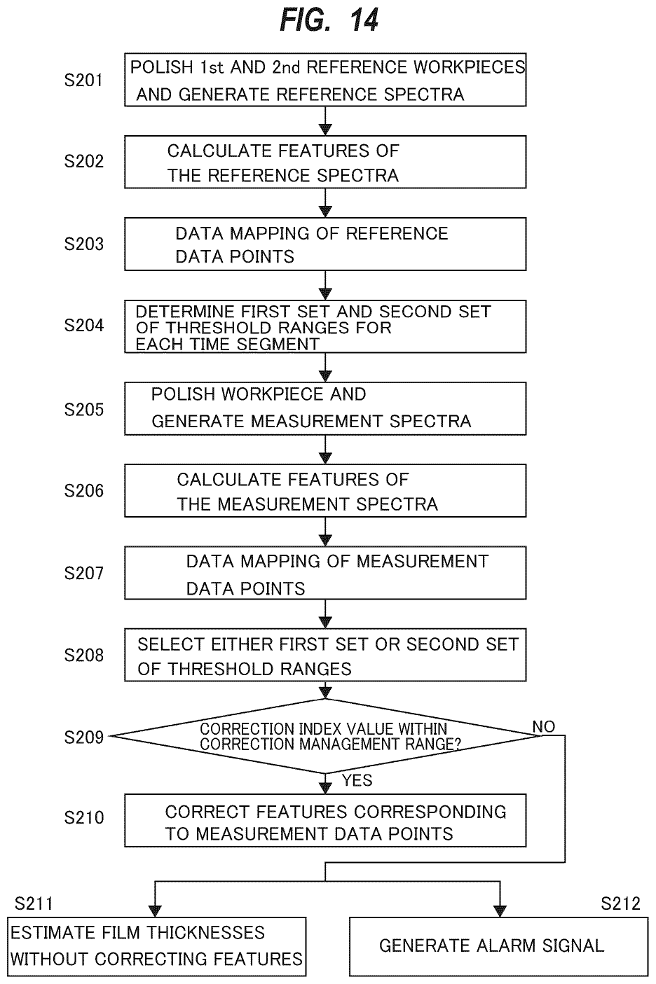

FIG. 14 is a flow chart of the embodiment described with reference to FIGS. 12 and 13.

In step S201, while the polishing table 3 is rotating, the first reference workpiece is pressed against the polishing pad 2 on the polishing table 3, so that the first reference workpiece is polished. In each of the time segments during polishing of the first reference workpiece, the optical sensor head 25 emits the light to a plurality of film-thickness measurement points on the first reference workpiece, and the processing system 30 generates a plurality of reference spectra of reflected light from the plurality of film-thickness measurement points on the first reference workpiece. Similarly, while the polishing table 3 is rotating, the second reference workpiece is pressed against the polishing pad 2 on the polishing table 3, so that the second reference workpiece is polished. In each of the time segments during polishing of the second reference workpiece, the optical sensor head 25 emits the light to a plurality of film-thickness measurement points on the second reference workpiece, and the processing system 30 generates a plurality of reference spectra of reflected light from the plurality of film-thickness measurement points on the second reference workpiece.

In step S202, the processing system 30 calculates a plurality of features of the plurality of reference spectra obtained from polishing of the first reference workpiece and a plurality of features of the plurality of reference spectra obtained from polishing of the second reference workpiece.

In step S203, the processing system 30 performs data mapping by plotting, on the coordinate system, a plurality of reference data points FD specified or determined by a plurality of times at which the plurality of reference spectra were generated in the polishing of the first reference workpiece and the plurality of corresponding features (see FIG. 12). Similarly, the processing system 30 performs data mapping by plotting, on the coordinate system, a plurality of reference data points FD specified or determined by a plurality of times at which the plurality of reference spectra were generated in the polishing of the second reference workpiece and the plurality of corresponding features (see FIG. 12).

In step S204, the processing system 30 determines the first set of threshold ranges TR1 defined for the time segments within the polishing time of the first reference workpiece based on the plurality reference data points FD on the coordinate system (see FIG. 12). Similarly, the processing system 30 determines the second set of threshold ranges TR2 defined for the time segments within the polishing time of the second reference workpiece based on the plurality reference data points FD on the coordinate system (see FIG. 12).

In step S205, the workpiece W is pressed against the polishing pad 2 on the polishing table 3 while the polishing table 3 is rotating, so that the workpiece W is polished. In each of the time segments during polishing of the workpiece W, the optical sensor head 25 emits the light onto the plurality of film-thickness measurement points on the workpiece W, and the processing system 30 generates the plurality of measurement spectra of the reflected light from the plurality of film-thickness measurement points.

In step S206, the processing system 30 calculates the plurality of features of the plurality of measurement spectra.

In step S207, the processing system 30 performs data mapping by plotting, on the coordinate system, the plurality of measurement data points MD specified or determined by a plurality of times at which the plurality of measurement spectra were generated and the plurality of features of the plurality of measurement spectra (see FIG. 13).

In step S208, the processing system 30 selects either the first set of threshold ranges TR1 or the second set of threshold ranges TR2 based on the change in the plurality of measurement data points MD over the polishing time of the workpiece W.

In step S209, the processing system 30 determines the correction index value representing the number of measurement data points MD existing within the selected first set of threshold range TR1 or second set of threshold range TR2, and determines whether the correction index value is within the predetermined correction management range.

In step S210, if the correction index value is within the correction management range, the processing system 30 corrects the features corresponding to the measurement data points MD by moving the measurement data points MD on the coordinate system until the measurement data points MD fall within the corresponding threshold range TR1 or TR2 (see FIG. 9). In one embodiment, the processing system 30 generates a plurality of corrected measurement spectra by converting the corrected features into a plurality of measurement spectra. The processing system 30 determines (or estimates) a plurality of film thicknesses at the plurality of film-thickness measurement points on the workpiece W from the plurality of corrected measurement spectra. In another embodiment, the processing system 30 determines (or estimates) a plurality of film thicknesses at the plurality of film-thickness measurement points on the workpiece W from the plurality of corrected features without generating the corrected measurement spectra.

In step S211, when the correction index value is larger than the upper limit of the correction management range, the processing system 30 determines (or estimates) a plurality of film thicknesses at the plurality of film-thickness measurement points on the workpiece W from the plurality of measurement spectra without correcting the features corresponding to the plurality of measurement data points MD.

In step S212, when the correction index value is less than the lower limit of the correction management range, the processing system 30 generates the alarm signal. The processing system 30 may send the alarm signal to the operation controller 9 to stop polishing of the workpiece W.

In the embodiments described with reference to FIGS. 12 to 14, two or more sets of threshold ranges are prepared in advance. In one embodiment, the processing system 30 may create a new set of thresholds from measurement spectra obtained during polishing of the workpiece W. For example, in an initial stage of polishing of the workpiece W, the processing system 30 has only the first set of threshold ranges TR1 shown in FIG. 12. The processing system 30 then creates the second set of threshold ranges TR2 shown in FIG. 12 from measurement spectra obtained during polishing of the workpiece W.

When the measurement data points MD show an upward trend with the polishing time of the workpiece as shown in FIG. 13, the measurement data points MD are outside the first set of threshold ranges TR1 of FIG. 12. Therefore, the processing system 30 generates an alarm signal and instructs the polishing apparatus to stop polishing the workpiece. However, the upward trend shown in FIG. 13 may be due to a workpiece of a different type than the workpiece that should be polished, and may not be due to a malfunction of the polishing apparatus.

Therefore, in this embodiment, when the correction index value is smaller than the lower limit of the correction management range in consecutive time segments during polishing of the workpiece W, the processing system 30 creates a plurality of new threshold ranges on the coordinate system corresponding to the above-mentioned consecutive time segments from a plurality of measurement data points obtained in these consecutive time segments.

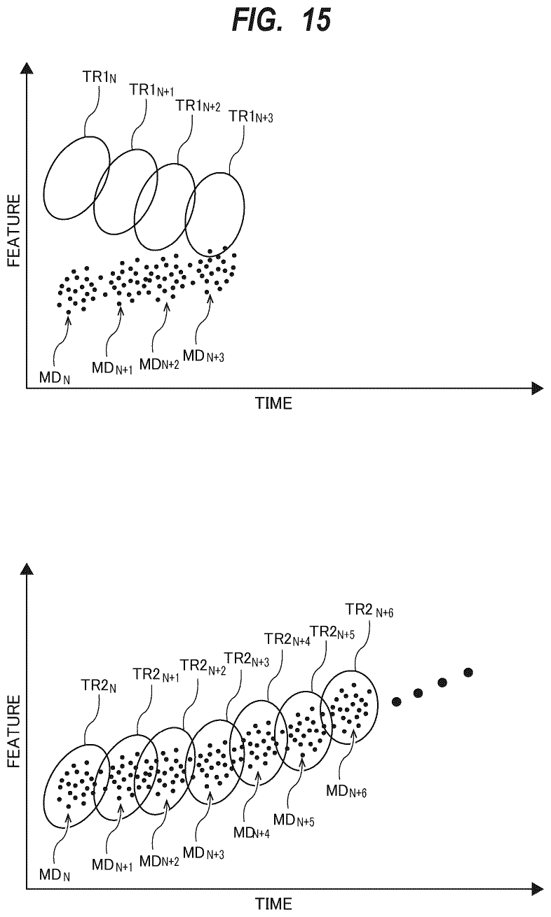

For example, as shown in FIG. 15, when a plurality of measurement data points MD_{N}, MD_{N+1}, MD_{N+2}, MD_{N+3}, which were obtained in consecutive time segments during polishing of the workpiece W, deviate from preset threshold ranges TR1_{N}, TR1_{N+1}, TR1_{N+2}, TR1_{N+3}, the processing system 30 creates new threshold ranges TR2_{N}, TR2_{N+1}, TR2_{N+2}, TR2_{N+3} . . . from the plurality of measurement data points MD_{N}, MD_{N+1}, MD_{N+2}, MD_{N+3} . . . , respectively. In one embodiment, the consecutive time segments are in an initial time of polishing the workpiece W. When the next workpiece is polished, the newly created threshold ranges TR2_{N}, TR2_{N+1}, TR2_{N+2}, TR2_{N+3} . . . are used. The processing system 30 can correctly inspect a measurement spectrum using the newly created threshold range.

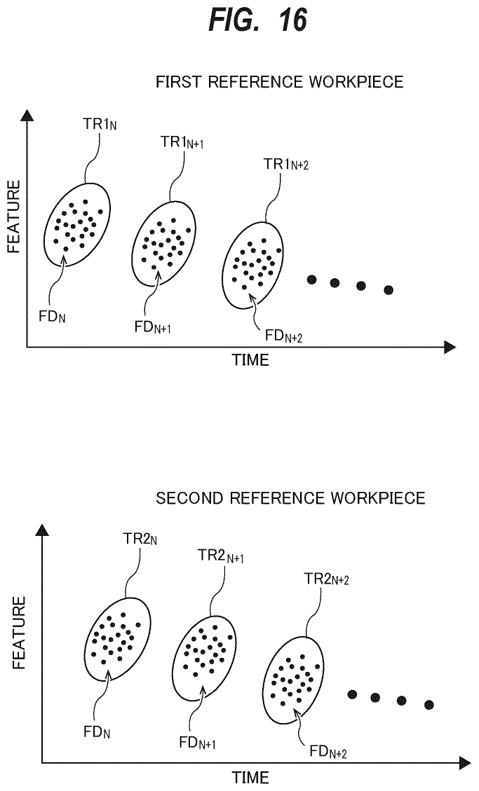

Next, still another embodiment for creating the threshold range will be described with reference to FIG. 16 to FIG. 18. In this example, a first reference workpiece and a second reference workpiece having the same surface structure are used to create a first threshold range and a second threshold range for each of the time segments during polishing of the first reference workpiece and the second reference workpiece.

As shown in FIG. 16, the first reference workpiece is polished by the polishing apparatus. A plurality of first threshold ranges TR1 (TR1_{N}, TR1_{N+1}, TR1_{N+2} . . . ) corresponding to a plurality of time segments during polishing of the first reference workpiece are created from a plurality of reference data points FD (FD_{N}, FD_{N+1}, FD_{N+2} . . . ) obtained during polishing of the first reference workpiece. Similarly, the second reference workpiece is polished by the polishing apparatus. A plurality of second threshold ranges TR2 (TR2_{N}, TR2_{N+1}, TR2_{N+2} . . . ) corresponding to a plurality of time segments during polishing of the second reference workpiece are created from a plurality of reference data points FD (FD_{N}, FD_{N+1}, FD_{N+2} . . . ) obtained during polishing of the second reference workpiece.

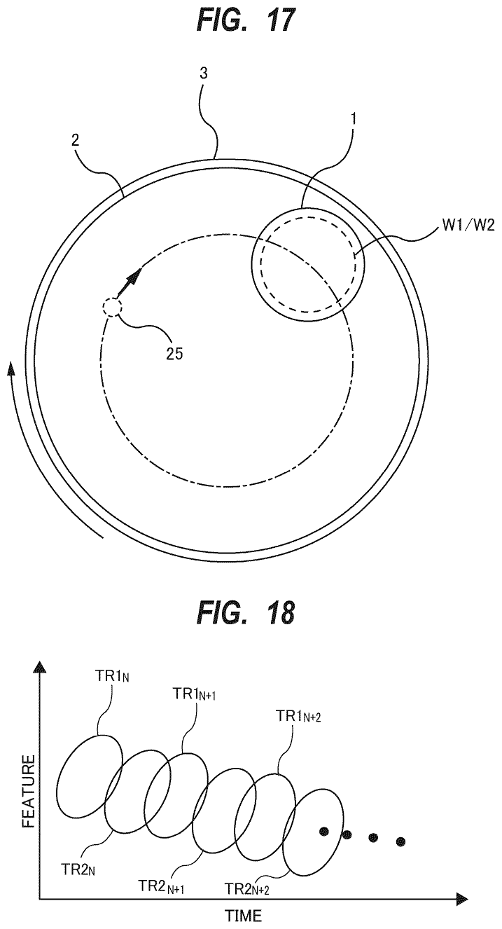

FIG. 17 is a top view showing an example of a positional relationship between the optical sensor head 25 and the polishing head 1. As shown in FIG. 17, during polishing of the first reference workpiece W1, the optical sensor head 25 emits the light onto a plurality of film-thickness measurement points on the surface of the first reference workpiece W1 while moving across the surface of the first reference workpiece W1 with the rotation of the polishing table 3. Similarly, during polishing of the second reference workpiece W2, the optical sensor head 25 emits the light onto a plurality of film-thickness measurement points on the surface of the second reference workpiece W2 while moving across the surface of the second reference workpiece W2 with the rotation of the polishing table 3.

The position of the optical sensor head 25 relative to the first reference workpiece W1 at the start of polishing the first reference workpiece W1 may be different from the position of the optical sensor head 25 relative to the second reference workpiece W2 at the start of polishing the second reference workpiece W2.

Specifically, a time when the optical sensor head 25 first moves across the surface of the first reference workpiece W1 may be different from a time when the optical sensor head 25 first moves across the surface of the second reference workpiece W2. For this reason, positions of the plurality of threshold ranges TR1 on a time axis may be different from positions of the plurality of threshold ranges TR2 on the time axis, as shown in FIG. 16.

The processing system 30 creates a plurality of threshold ranges (TR1_{N}, TR2_{N}, TR1_{N+1}, TR2_{N+1}, TR1_{N+2}, TR2_{N+2}, . . . ) corresponding to different time segments as shown in FIG. 18 by combining the plurality of first threshold ranges TR1 (TR1_{N}, TR1_{N+1}, TR1_{N+2} . . . ) and the plurality of second threshold ranges TR2 (TR2_{N}, TR2_{N+1}, TR2_{N+2} . . . ) shown in FIG. 16. More specifically, the first threshold ranges TR1 and the second threshold ranges TR2 are combined by arranging the plurality of first threshold ranges TR1 (TR1_{N}, TR1_{N+1}, TR1_{N+2} . . . ) and the plurality of second threshold ranges TR2 (TR2_{N}, TR2_{N+1}, TR2_{N+2} . . . ) along the time axis.

The plurality of threshold ranges obtained in this manner reflect differences in the initial positions of the optical sensor head 25, so that the processing system 30 can correctly inspect the measurement spectrum using the threshold ranges shown in FIG. 18.

In this embodiment, two reference workpieces are used to create multiple threshold ranges corresponding to different time segments. It is noted, however, three or more reference workpieces may be used to create multiple threshold ranges corresponding to different time segments.

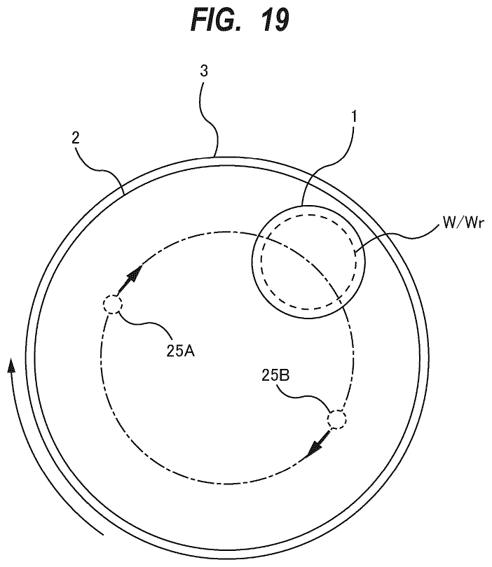

FIG. 19 is a top view showing an embodiment of the polishing apparatus including a first optical sensor head 25A and a second optical sensor head 25B. Each of the optical sensor heads 25A and 25B is optically coupled to the light source 22 and the spectrometer 27 shown in FIG. 2. The optical sensor heads 25A and 25B are disposed at different positions in a circumferential direction of the polishing table 3. The optical sensor heads 25A and 25B are located at the same distance from the center of the polishing table 3. Other configurations of the polishing apparatus are the same as those of the embodiments described with reference to FIGS. 1 and 2, and therefore repeated description thereof will be omitted.

As shown in FIG. 19, while the workpiece W is being polished, the optical sensor heads 25A, 25B rotate together with the polishing table 3 while moving across the surface of the workpiece W alternately (i.e., at different timings).

The threshold ranges are created based on reference data points obtained during polishing of a reference workpiece Wr. During polishing of the reference workpiece Wr, the optical sensor heads 25A, 25B rotate together with the polishing table 3 while moving across the surface of the reference workpiece Wr alternately (i.e., at different times).

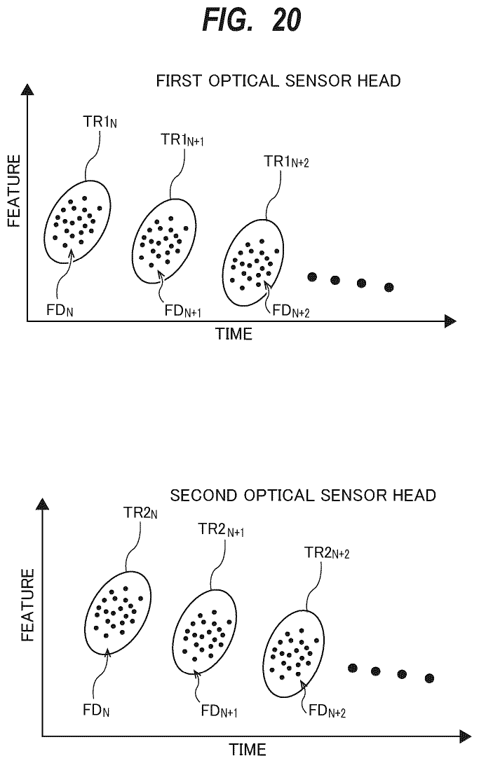

FIG. 20 is a diagram showing examples of a plurality of first threshold ranges TR1 (TR1_{N}, TR1_{N+1}, TR1_{N+2} . . . ) and a plurality of second threshold ranges TR2 (TR2_{N}, TR2_{N+1}, TR2_{N+2} . . . ). The plurality of first threshold ranges TR1 (TR1_{N}, TR1_{N+1}, TR1_{N+2} . . . ) are created from a plurality of reference data points FD (FD_{N}, FD_{N+1}, FD_{N+2} . . . ) obtained by the light irradiation from the first optical sensor head 25A during polishing of the reference workpiece Wr. The plurality of second threshold ranges TR2 (TR2_{N}, TR2_{N+1}, TR2_{N+2} . . . ) are created from a plurality of reference data points FD (FD_{N}, FD_{N+1}, FD_{N+2} . . . ) obtained by the light irradiation from the second optical sensor head 25B during polishing of the reference workpiece Wr.

As shown in FIG. 20, the positions of the plurality of threshold ranges TR1 on the time axis are different from the positions of the plurality of threshold ranges TR2 on the time axis due to differences in the positions of the optical sensor heads 25A and 25B. In addition, the positions of the plurality of threshold ranges TR1 on the feature axis are different from the positions of the plurality of threshold ranges TR2 on the feature axis due to individual differences between the optical sensor heads 25A and 25B.

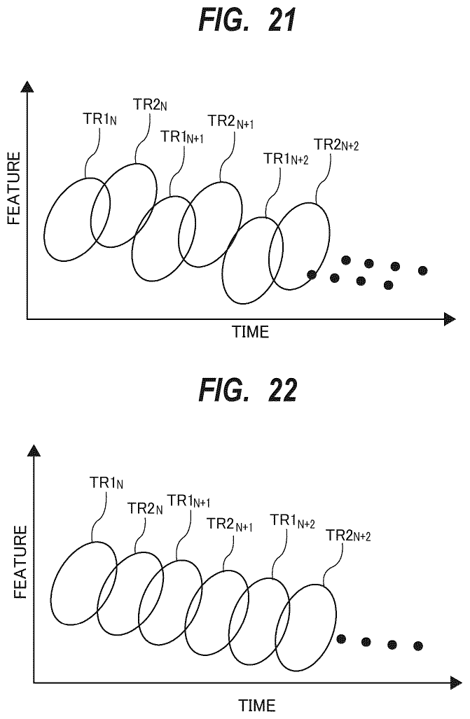

Thus, the processing system 30 creates a plurality of threshold ranges (TR1_{N}, TR2_{N}, TR1_{N+1}, TR1_{N+2}, . . . ) corresponding to different time segments by combining the plurality of first threshold ranges TR1 (TR1_{N}, TR1_{N+1}, TR1_{N+2}, . . . ) and the plurality of second threshold ranges TR2 (TR2_{N}, TR2_{N+1}, TR2_{N+2}, . . . ) shown in FIG. 20. More specifically, as shown in FIG. 21, the processing system 30 arranges the plurality of first threshold ranges TR1 and the plurality of second threshold ranges TR2 along the time axis, and further, as shown in FIG. 22, the processing system 30 aligns the plurality of first threshold ranges TR1 and the plurality of second threshold ranges TR2 by moving at least one of the plurality of first threshold ranges TR1 and the plurality of second threshold ranges TR2 along the feature axis.

The plurality of threshold ranges obtained in this manner reflect differences in the arrangement and individual differences of the optical sensor heads 25A, 25B, so that the processing system 30 can correctly inspect a measurement spectrum using the threshold ranges shown in FIG. 22.

In this embodiment, two optical sensor heads 25A, 25B are used to create the plurality of threshold ranges corresponding to different time segments, but three or more optical sensor heads may be used to create the plurality of threshold ranges corresponding to different time segments.

The processing system 30 operates according to instructions included in the program electronically stored in the memory 30a. The program for causing the processing system 30 to execute the steps according to the embodiments described with reference to FIGS. 1 to 22 is stored in a computer-readable storage medium, which is a non-transitory tangible medium, and is provided to the processing system 30 via the storage medium. Alternatively, the program may be input to the processing system 30 via a communication network, such as the Internet or a local area network.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A method of inspecting a spectrum of reflected light from a workpiece, comprising:
polishing the workpiece by pressing the workpiece against a polishing pad on a polishing table while rotating the polishing table;
irradiating a plurality of film-thickness measurement points on the workpiece with light from an optical sensor head in each time segment during polishing of the workpiece;
generating a plurality of measurement spectra of reflected light from the plurality of film-thickness measurement points;
calculating a plurality of features of the plurality of measurement spectra;
performing data mapping by plotting, on a coordinate system, a plurality of measurement data points specified by a plurality of times at which the plurality of measurement spectra were generated and the plurality of features of the plurality of measurement spectra;
determining a correction index value representing the number of measurement data points existing within a threshold range defined on the coordinate system for each time segment; and
determining whether the correction index value is within a correction management range.

2. The method according to claim 1, further comprising:
correcting the plurality of features by moving the plurality of measurement data points on the coordinate system until the plurality of measurement data points fall within the threshold range when the correction index value is within the correction management range.

3. The method according to claim 1, further comprising:
generating an alarm signal when the correction index value is smaller than a lower limit of the correction management range.

4. The method according to claim 1, further comprising:
polishing a reference workpiece by pressing a reference workpiece against the polishing pad while rotating the polishing table;
irradiating a plurality of film-thickness measurement points on the reference workpiece with the light from the optical sensor head in each time segment during polishing of the reference workpiece;
generating a plurality of reference spectra of reflected light from the plurality of film-thickness measurement points;
calculating a plurality of features of the plurality of reference spectra;
performing data mapping by plotting, on the coordinate system, a plurality of reference data points specified by a plurality of times at which the plurality of reference spectra were generated and the plurality of features of the plurality of reference spectra; and
creating a threshold range for each time segment during polishing of the reference workpiece based on the plurality of reference data points on the coordinate system.

5. The method according to claim 4, wherein the threshold range is a range within a predetermined Mahalanobis distance from a datum point of the plurality of reference data points.

6. The method according to claim 4, further comprising:
updating the plurality of reference data points by adding the plurality of measurement data points to the plurality of reference data points when the correction index value is larger than an upper limit of the correction management range; and
updating the threshold range based on the plurality of updated reference data points.

7. The method according to claim 4, further comprising:
selecting either a first set of threshold ranges or a second set of threshold ranges based on a change in the plurality of measurement data points over time as the workpiece is polished,
wherein the threshold range is one of a plurality of threshold ranges in the selected one of the first set and the second set,
the first set of threshold ranges is predetermined from a plurality of reference data points obtained during polishing of a first reference workpiece, and
the second set of threshold ranges is predetermined from a plurality of reference data points obtained during polishing of a second reference workpiece having a different surface structure than that of the first reference workpiece.

8. The method according to claim 4, wherein the reference workpiece comprises a first reference workpiece and a second reference workpiece, and
the method further comprises creating a plurality of threshold ranges corresponding to different time segments by combining a first threshold range created from a plurality of reference data points obtained during polishing of the first reference workpiece and a second threshold range created from a plurality of reference data points obtained during polishing of the second reference workpiece.

9. The method according to claim 4, wherein the optical sensor head comprises a first optical sensor head and a second optical sensor head disposed at different positions within the polishing table, and
the method further comprises creating a plurality of threshold ranges corresponding to different time segments by combining a first threshold range created from a plurality of reference data points obtained by light irradiation from the first optical sensor head during polishing of the reference workpiece and a second threshold range created from a plurality of reference data points obtained by light irradiation from the second optical sensor head during polishing of the reference workpiece.

10. The method according to claim 1, wherein each of the plurality of features includes at least a k-th principal component (k is a natural number) obtained by performing principal component analysis on a data set including a plurality of intensities of the reflected light at a plurality of wavelengths of each measurement spectrum.

11. The method according to claim 1, further comprising:
creating a plurality of new threshold ranges corresponding to consecutive time segments from a plurality of measurement data points acquired in the consecutive time segments when the correction index value is smaller than a lower limit of the correction management range in the consecutive time segments during polishing of the workpiece.

12. A polishing apparatus for a workpiece, comprising:
a polishing table;
a table motor configured to rotate the polishing table;
a polishing head configured to press the workpiece against a polishing pad on the polishing table to polish the workpiece;
an optical sensor head configured to emit light to a plurality of film-thickness measurement points on the workpiece in each time segment during polishing of the workpiece; and
a processing system configured to generate a plurality of measurement spectra of reflected light from the plurality of film-thickness measurement points,
wherein the processing system is configured to:
calculate a plurality of features of the plurality of measurement spectra;
perform data mapping by plotting, on a coordinate system, a plurality of measurement data points specified by a plurality of times at which the plurality of measurement spectra were generated and the plurality of features of the plurality of measurement spectra;
determine a correction index value representing the number of measurement data points existing within a threshold range defined on the coordinate system for each time segment; and
determine whether the correction index value is within a correction management range.

13. The polishing apparatus according to claim 12, wherein the processing system is configured to correct the plurality of features by moving the plurality of measurement data points on the coordinate system until the plurality of measurement data points fall within the threshold range when the correction index value is within the correction management range.

14. The polishing apparatus according to claim 12, wherein the processing system is configured to generate an alarm signal when the correction index value is smaller than a lower limit of the correction management range.

15. The polishing apparatus according to claim 12, wherein the processing system is configured to select either a first set of threshold ranges or a second set of threshold ranges based on a change in the plurality of measurement data points over time as the workpiece is polished,
wherein the threshold range is one of a plurality of threshold ranges in the selected one of the first set and the second set,
the first set of threshold ranges is predetermined from a plurality of reference data points obtained during polishing of a first reference workpiece, and
the second set of threshold ranges is predetermined from a plurality of reference data points obtained during polishing of a second reference workpiece having a different surface structure than that of the first reference workpiece.

16. The polishing apparatus according to claim 12, wherein the processing system is configured to:
perform a principal component analysis on a data set including a plurality of intensities of the reflected light at a plurality of wavelengths of each measurement spectrum; and
determine a feature including at least a k-th principal component (k is a natural number) obtained from the principal component analysis.

17. The polishing apparatus according to claim 12, wherein the processing system is configured to create a plurality of new threshold ranges corresponding to consecutive time segments from a plurality of measurement data points acquired in the consecutive time segments when the correction index value is smaller than a lower limit of the correction management range in the consecutive time segments during polishing of the workpiece.

18. The polishing apparatus according to claim 12, wherein the processing system is configured to determine the threshold range, the threshold range being within a predetermined Mahalanobis distance from a datum point of a plurality of reference data points obtained from polishing a reference workpiece.

19. The polishing apparatus according to claim 18, wherein the processing system is configured to:
update the plurality of reference data points by adding the plurality of measurement data points to the plurality of reference data points when the correction index value is larger than an upper limit of the correction management range; and
update the threshold range based on the plurality of updated reference data points.
